(19) United States
(12) Patent Application Publication
(10) Pub. No.: US 2015/0156916 A1
(43) Pub. Date: Jun. 4, 2015

(54) ELECTRONIC DEVICE

(71) Applicants: INVENTEC CORPORATION, Taipei City (TW); INVENTEC (PUDONG) TECHNOLOGY CORPORATION, Shanghai (CN)

(72) Inventors: Yi-Lun CHENG, Taipei City (TW); Chih-Kai YANG, Taipei City (TW)

(73) Assignees: INVENTEC CORPORATION, Taipei City (TW); INVENTEC (PUDONG) TECHNOLOGY CORPORATION, Shanghai (CN)

(21) Appl. No.: 14/244,694

(22) Filed: Apr. 3, 2014

(30) Foreign Application Priority Data
Nov. 29, 2013 (CN) 201310630309.4

(51) Int. Cl. H05K 7/20

(52) U.S. Cl. CPC H05K 7/20136

(57) ABSTRACT

An electronic device includes a case, an airflow generator and a support block. The case has an abutting surface located inside the case. The airflow generator is disposed inside the case and includes an axle part and a plurality of blades disposed around the axle part. The support block is disposed on the axle part and protrudes towards the abutting surface, or is disposed on the abutting surface and protrudes towards the axle part.

### CROSS-REFERENCE TO RELATED APPLICATIONS

This non-provisional application claims priority under 35 U.S.C. §119(a) on Patent Application No(s). 201310630309.4 filed in China, P.R.C. on 2013/11/29, the entire contents of which are hereby incorporated by reference.

### BACKGROUND OF THE INVENTION

1. Technical Field of the Invention

The disclosure relates to an electronic device, more particularly to an electronic device with an airflow generator.

2. Description of the Related Art

In today's electronic device, an airflow generator such as fan is often employed for the heat dissipation. However, when the user is using the electronic device, their hands often press the electronic device. This results in the deformation of the case and this case therefore abuts on the fans inside the electronic device. As a result, a large area of the case may touch the fans.

A great amount of friction and friction torque are generated as the fans are pressed by a large area of the case. Hence, the rotational speed is decreased and the noise level increases, which reduces the heat dissipation efficiency of the fans.

### SUMMARY OF THE INVENTION

An electronic device comprises a case, an airflow generator and a support block. The case has an abutting surface located inside the case. The airflow generator is disposed inside the case and comprises an axle part and a plurality of blades disposed around the axle part. The support block is disposed on the axle part and protrudes towards the abutting surface, or is disposed on the abutting surface and protrudes towards the axle part.

### BRIEF DESCRIPTION OF THE DRAWINGS

The present disclosure will become more fully understood from the detailed description given hereinbelow, along with the accompanying drawings which are for illustration only, thus are not limitative of the present disclosure, and wherein:

FIG. 1 is an electronic device according to a first embodiment of the disclosure;

FIG. 2 is an electronic device according to a second embodiment of the disclosure;

FIG. 3 is an electronic device according to the second embodiment of the disclosure;

FIG. 4 is an electronic device according to the second embodiment of the disclosure; and

FIG. 5 is an electronic device according to the second embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

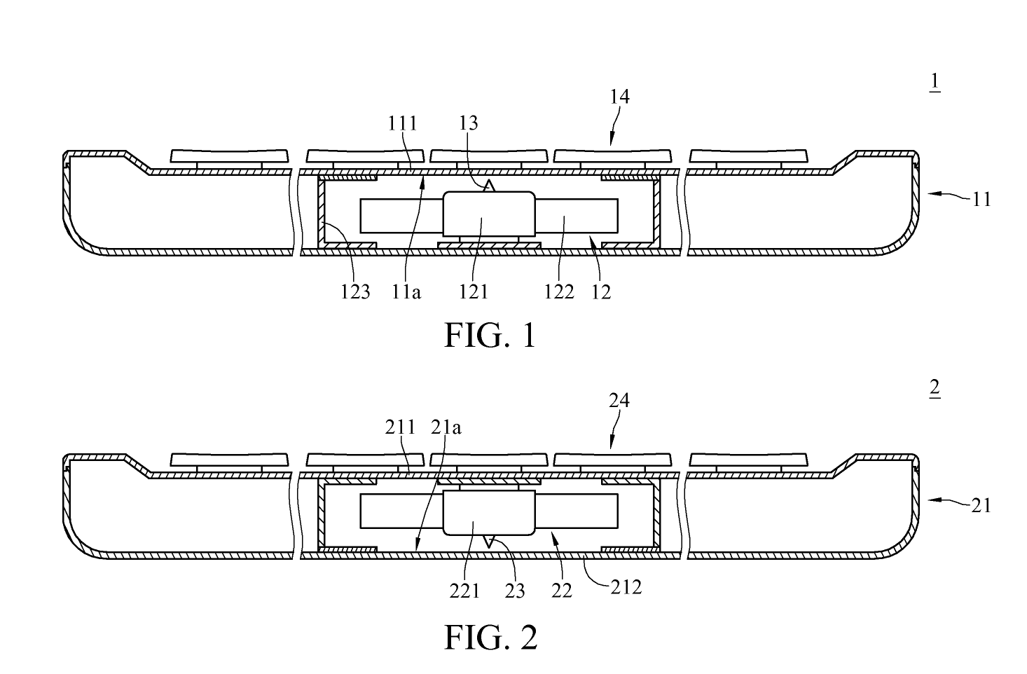

FIG. 1 is an electronic device according to a first embodiment of the disclosure. As seen in FIG. 1, in this embodiment, an electronic device 1 comprises a case 11, an airflow generator 12, a support block 13 and a keyboard 14. The case has an abutting surface 11 a located in the case 11. The case 11 comprises a keyboard support member 111 for carrying the keyboard 14. The abutting surface 11 a is located on the keyboard support member 111.

The air generator 12, disposed in the case 11, comprises an axle part 121, a plurality of blades 122 and a frame 123. The blades 122 are disposed around and directly connected to the axle part 121. The frame 123 is disposed around and surrounds the axle part 121 and the blades 122. The keyboard support member 111 is located between the keyboard 14 and the air generator 12.

The support block 13 is disposed on the axle part 121 and protrudes towards the abutting surface 11a. The support block 13 is in a conical shape and is located on the rotational center of the axle part 121.

Thus, the user may apply pressure on the keyboard 14 and the keyboard support member 11 to move accordingly when using the keyboard 14, and this makes the abutting surface 11a of the keyboard support member 111 touch the support block 13. Since there is merely the point contact between the keyboard support member 111 and the support block 13, and the contact point between them is at the rotational center of the axle part 121, the friction and the friction torque between them are reduced. Thereby, this avoids the decrease of the rotational speed of the airflow generator 12, which enables it to work normally.

FIG. 2 is an electronic device 2 according to a second embodiment of the disclosure. As seen in FIG. 2, the electronic device 2 is similar to the electronic device 1 shown in FIG. 1, so only the differences between them will be illustrated. In this embodiment, the case 21 comprises a bottom part 212. The abutting surface 21 is located on the bottom part 212, while the airflow generator 22 is located between the keyboard 24 and the bottom part 212.

Therefore, the user applies pressure on the keyboard 24 and the keyboard support member 211 to move accordingly when using the keyboard 24 and this applies another pressure on the airflow generator 22. The support block 23 of the axle part 221 of the airflow generator 22 is in contact with the bottom part 212. Since there is merely the point contact between the support block 13 and the bottom part 212 of the case 21 and the contact point between them is at the rotational center of the axle part 221, the friction and the friction torque are reduced. Thereby, this avoids the decrease of the rotational speed of the airflow generator 22, which enables it to work normally.

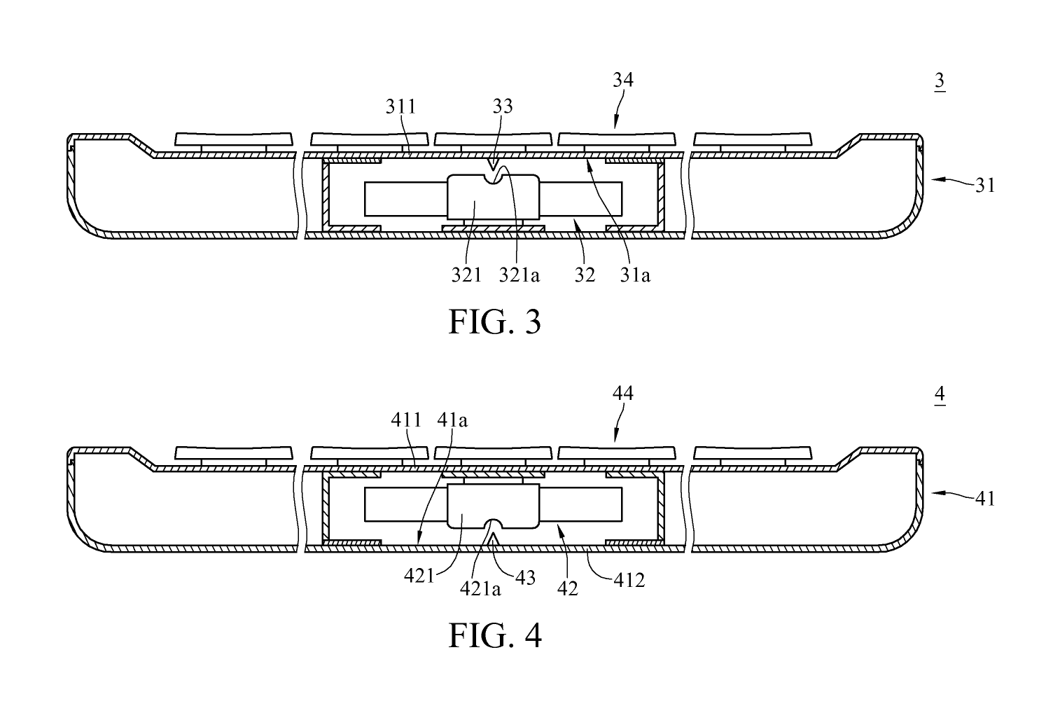

FIG. 3 is an electronic device according to the second embodiment of the disclosure. As seen in FIG. 3, the electronic device 3 is similar to the electronic device 1 shown in FIG. 1, so only the differences between them will be illustrated. In this embodiment, the support block 33 is disposed on the abutting surface 31a of the keyboard support member 311, and protrudes towards the axle part 321. The axle part 321 has a recess portion 321a located at the rotational center of the axle part 321. The support block 321 faces the recess portion 321a.

Consequently, the user applies pressure on the keyboard 34 and the keyboard support member 311 to move accordingly when using the keyboard 34, thereby making the support block 33 of the abutting surface 31a be in contact with the axle part 321 of the airflow generator 32. Furthermore, the support block 33 may touch the surface of the recess portion 321a of the axle part 321, so that the contact point of the support block 33 and the axle part 321 is at the rotational center of the axle part 321. Since there is merely the point contact between the support block 33 and the axle part 321 and the contact point between them is at the rotational center of the axle part 321, the friction and the friction torque between them are reduced. Thereby, this avoids the decrease of the rotational speed of the airflow generator 32, which enables it to work normally.

FIG. 4 is an electronic device 4 according to the second embodiment of the disclosure. As seen in FIG. 4, the electronic device 4 is similar to the electronic device 3 shown in FIG. 3, so only the differences between them will be illustrated. In this embodiment, a case 41 comprises a bottom part 412. The abutting surface 41a is located on the bottom part 412, and the airflow generator 42 is located between the keyboard 44 and the bottom part 412.

Hence, the user applies pressure on the keyboard 44 and the keyboard support member 411 when using the keyboard 44, thereby applying pressure on the airflow generator 42. The axle part 421 of the airflow generator 42, therefore, is in contact with the support block 43 of the abutting surface 41a, which is disposed on the bottom part 412. Moreover, the support block 43 can touch the surface of the recess portion 421a of the axle part 421, thereby making the contact position of the support block 43 and the axle part 421 be at the rotational center. Since there is merely the point contact between the support block 43 and the axle part 421 and the contact point between them is at the rotational center of the axle part 321, the friction and the friction torque between them are reduced. Thereby, this avoids the decrease of the rotational speed of the airflow generator 42, which enables it to work normally.

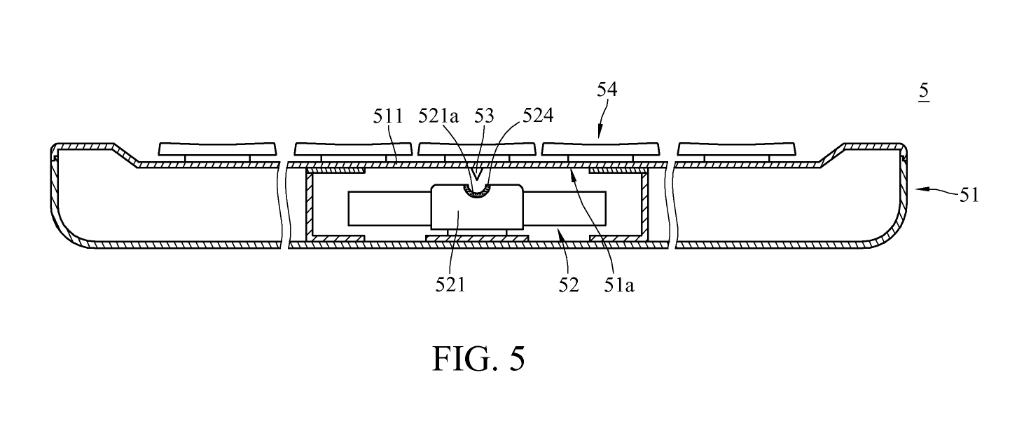

FIG. 5 is an electronic device according to the second embodiment of the disclosure. As seen in FIG. 5, the electronic device 5 is similar to the electronic device 3 shown in FIG. 3, so only the differences between them will be illustrated. In this embodiment, the airflow generator 52 further comprises an attracting member 524 disposed in the recess portion 521a of the axle part 521. In one embodiment, the material of the support block 53 is the magnetic material, while the material of the attracting member 524 is the magnetic conductive material such as iron, cobalt or nickel. In one embodiment, the material of the support block is 53 magnetic conductive material, while the material of the attracting member 524 is magnetic material. In one embodiment, the magnetism of the support block 53 and that of the abstract member 524 are opposite, namely magnetically attractive to each other. For instance, the magnetism of the support block 53 is N-pole while that of the abstract member 524 is S-pole, or the magnetism of the support block 53 is S-pole while that of the abstract member 524 is N-pole.

Therefore, the user applies pressure on the keyboard 54 and the keyboard support member 511 when using the keyboard 44, so that the support block 53 of the abutting surface 51 a touches the axle part 521 of the airflow generator 52. Moreover, the support block 53 is attracted by the attracting member 524 in the recess portion 521a of the axle part 521, so that the support block 53 can be guided to the inside of the recess portion 521a of the axle part 521, namely the rotational center of the axle part 521. Since there is merely the point contact between the support block 53 and the attracting member 524 and the contact point between them is at the rotational center of the axle part 321, the friction and the friction torque between them are reduced. Thereby, this avoids the decrease of the rotational speed of the airflow generator 52, which enables it to work normally.

To sum up, in the electronic device in the above-mentioned embodiments of the disclosure, when the case is pressed, the support block is in contact with the airflow generator of the case at a point. This prevents a large area of the case from squeezing the airflow generator. In other words, even though the case is pressed by the external force, the friction and the friction torque on the airflow generator is minimized. This avoids the decrease of the rotational speed of the airflow generator, so that the airflow generator can work normally.

What is claimed is:

1. An electronic device comprising:
a case having an abutting surface located inside the case;
an airflow generator disposed inside the case, the airflow generator comprising:
an axle part; and
a plurality of blades disposed around the axle part; and
a support block being disposed on one of the axle part and the abutting surface, and protruding towards the other one of the axle part and the abutting surface.

2. The electronic device according to claim 1, wherein the support block is disposed on the axle part and protrudes towards the abutting surface.

3. The electronic device according to claim 1, wherein the support block is disposed on the abutting surface, the axle part has a recess portion and the support block faces the recess portion.

4. The electronic device according to claim 3, wherein the airflow generator further comprises an attracting member disposed in the recess portion, the material of the support block is magnetic material, while the material of the attracting member is magnetic conductive material.

5. The electronic device according to claim 3, wherein the airflow generator further comprises an attracting member disposed in the recess portion, the material of the support block is magnetic conductive material, while the material of the attracting member is magnetic material.

6. The electronic device according to claim 3, wherein the airflow generator further comprises an attracting member disposed in the recess portion, and the support block and the abstract member are magnetically attractive to each other.

7. The electronic device according to claim 1, wherein the airflow generator further comprises a frame, and the frame is disposed around the axle part and the blades.

8. The electronic device according to claim 1, further comprising a keyboard, wherein the case comprises a keyboard support member, the abutting surface is located on the keyboard support member, and the keyboard support member is located between the keyboard and the airflow generator.

9. The electronic device according to claim 1, further comprising a keyboard, wherein the case comprises a bottom part, the abutting surface is located on the bottom part, and the airflow generator is located between the keyboard and the bottom part.

10. The electronic device according to claim 1, the support block is in a conical shape.
